(19) United States
(12) Patent Application Publication
(10) Pub. No.: US 2010/0279694 A1
(43) Pub. Date: Nov. 4, 2010

(54) DISPLAY PANEL STRUCTURE, ELECTRONIC DEVICE USING THE SAME, AND MOBILE INFORMATION EQUIPMENT

(75) Inventors: Kenji Yagi, Kato (JP); Kazunori Katou, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/813,021

(22) Filed: Jun. 10, 2010

Related U.S. Application Data
(63) Continuation of application No. PCT/JP2007/001405, filed on Dec. 14, 2007.

(51) Int. Cl. H04W 36/00; H04W 88/02; H05K 7/00; G02F 1/1333

(52) U.S. Cl. 455/436; 455/566; 361/748; 349/58

(57) ABSTRACT

A display panel includes a display element having, on a front face of the display element, a screen, and a metal holding member for holding the display element together on a back face of the display element. A holding member is provided with a plurality of catch portions that extend from a back face of the holding member and grip end edge portions of the printed circuit board, and is also provided with a plurality of projections that project, around each of the plurality of catch portions, from the back face of the holding member. A printed circuit board is gripped by the plurality of catch portions provided on the back face of the holding member, and ground patterns provided on a surface of the printed circuit board come into close contact with the plurality of projections, so that an electrical connection is made between the display panel and the printed circuit board.

### CROSS-REFERENCE TO RELATED APPLICATIONS

This application is a continuing application, filed under 35 U.S.C. §111(a), of International Application PCT/JP2007/001405, filed on Dec. 14, 2007, the entire contents of which are incorporated herein by reference.

### FIELD

The embodiment discussed herein is related to a display panel structure, an electronic device using the same, and mobile information equipment. The embodiment discussed herein is applied, for example, to a thin mobile phone.

### BACKGROUND

In recent years, it has been increasingly desired to reduce the thickness of mobile phones and improve the appearance and usability thereof. Further reduction in the thickness of mobile phones requires reduction in size and thickness of individual parts of the mobile phone such as casings, batteries, printed circuit boards, and other electronic components. Further, there is an increasing trend in the use of a built-in antenna in a mobile phone in light of the appearance thereof. This requires a structure for housing an antenna efficiently in a small space within the casing.

According to conventional techniques, a casing (case) of a mobile phone is formed by molding a synthetic resin such as a polycarbonate resin or an ABS resin. A folding mobile phone having a receiver side (movable side) and a transmitter side (fixed side) coupled to each other by a hinge mechanism is known (see Japanese Laid-open Patent Publication No. 2005-303542). With such a mobile phone, a transmitter-side casing is composed of a front case having, on a surface of the front case, an operation portion, and a rear case that is arranged to make contact with the rear of the front case and has a battery containing portion therein. Further, an antenna (built-in antenna) of the mobile phone has a structure in which antenna elements made of metal are integrated with a bar-shaped support member made of a synthetic resin, and are located in a rear case along the upper side of the inside surface thereof.

There is also known a mobile phone having a structure in which a display side (movable side) casing and an operation portion side (fixed side) casing are coupled to each other by a slide mechanism so as to be slidable relative to each other (see Japanese Laid-open Patent Publication No. 2006-246353). Upon the use of such a mobile phone, a user slides the casings to the open direction for display or operation of the mobile phone. Upon the non-use of such a mobile phone, the user slides the casings to the closed direction; thereby to reduce the surface area thereof.

Incidentally, such a mobile phone often uses a plurality of radio waves based on different communication standards or different communication systems; accordingly the mobile phone is provided with a plurality of antenna elements covering different frequency bands. It is necessary to provide sufficient ground connections of individual portions in order to ensure antenna characteristics of the antenna elements, and to avoid the influence of radio waves in a variety of frequency bands emitted from the antenna elements inflicted on the functions of the individual portions. Specifically, it is necessary to make the ground connections reliable by making wide and short connections among individual ground electrodes or ground lines of electronic components, a display panel, flexible cables (flexible circuit boards), shield patterns, shield cases, printed circuit boards, batteries, casings, and the like.

FIG. 26 is a cross-sectional view illustrating a fixing part of a conventional display panel structure.

Referring to FIG. 26, a conventional display panel structure HKj includes a display panel 21j and a printed circuit board 22j. A liquid crystal display element DL is held by a metallic holding plate HB; thereby to constitute the display panel 21j. The holding plate HB has a fixing terminal TT on an end portion of the holding plate HB. The display panel 21j is fitted into a display portion of a front case 11j with a screen HG facing outward. The display panel 21j, the printed circuit board 22j provided on the back thereof, a member BZ such as a slide mechanism are fastened together with a screw NJ; thereby they are fixed together.

A surface of the printed circuit board 22j is provided with a ground pattern at a position corresponding to the position of the fixing terminal TT. Thus, the screw NJ is tightened up, so that the ground pattern comes into close contact with the fixing terminal TT, resulting in providing a ground connection.

As discussed above, in the conventional technique, the display panel structure HKj has a structure in which the front case 11j and other members are fastened together with the screw NJ. In such a case, however, thicknesses of the individual members are added together, which means that it is impossible to reduce the thickness of the casing to a predetermined level or less.

Thus, in order to meet a demand for reduction in the thickness of a mobile phone as described above, it is desirable to devise a display panel structure which eliminates the need for the fastening described above and provides reliable ground connections.

Further, as more frequency bands are used and wider frequency bands are used, a ground connection is to be made further reliably between the display panel 21j and the printed circuit board 22j to ensure antenna characteristics and to avoid the influence of radio waves in a variety of frequency bands.

### SUMMARY

According to an aspect of the invention (embodiment), a display panel structure includes a display panel, and a printed circuit board. The display panel includes a display element having, on a front face of the display element, a screen, and a metal holding member for holding the display element together on a back face of the display element. The holding member is provided with a plurality of catch portions that extend from a back face of the holding member and grip end edge portions of the printed circuit board, and is also provided with a plurality of projections that project, around each of the plurality of catch portions, from the back face of the holding member. The printed circuit board is gripped by the plurality of catch portions provided on the back face of the holding member, and ground patterns provided on a surface of the printed circuit board come into close contact with the plurality of projections, so that an electrical connection is made between the display panel and the printed circuit board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a front view illustrating a mobile phone according to an embodiment;

FIG. 2A is a back view illustrating a mobile phone, and FIG. 2B is a right side view illustrating a mobile phone;

FIG. 3 is a top plan view illustrating a mobile phone;

FIG. 4 is a perspective view illustrating a mobile phone;

FIG. 5 is an exploded perspective view illustrating casings of a mobile phone;

FIG. 6 is a left side cross-sectional view illustrating a fixed side of a mobile phone;

FIG. 7 is an exploded perspective view illustrating a fixed side of a mobile phone;

FIG. 8 is a front view illustrating an intermediate support member;

FIG. 9 is a back view illustrating an intermediate support member;

FIGS. 10A and 10B are side views illustrating an intermediate support member;

FIG. 11 is a front view illustrating a main circuit board;

FIG. 12 is a back view illustrating a main circuit board;

FIG. 13A is a front view illustrating a sub circuit board, and FIG. 13B is a back view illustrating a sub circuit board;

FIG. 14 is a partial enlarged view illustrating a main circuit board;

FIG. 15 is a block diagram illustrating the entire circuit of a mobile phone;

FIG. 16 is an exploded perspective view illustrating a receiver-side casing of a mobile phone;

FIG. 17 is an exploded perspective view illustrating a receiver-side casing of a mobile phone;

FIG. 18 is a front view illustrating a display circuit board;

FIG. 19 is a back view illustrating a display circuit board;

FIG. 20 is a perspective view illustrating a display panel structure;

FIG. 21 is an exploded perspective view illustrating a display panel structure;

FIG. 22 is an enlarged perspective view illustrating the vicinity of a catch portion of a holding member;

FIG. 23 is an enlarged cross-sectional view illustrating the vicinity of a catch portion of a holding member;

FIG. 24 is an enlarged side view illustrating the vicinity of a catch portion of a holding member;

FIG. 25 is a cross-sectional view illustrating a fixing part of a display panel structure and a front case; and

FIG. 26 is a cross-sectional view illustrating a fixing part of a conventional display panel structure.

### DESCRIPTION OF EMBODIMENT(S)

Preferred embodiments of the present invention will be explained with reference to accompanying drawings.

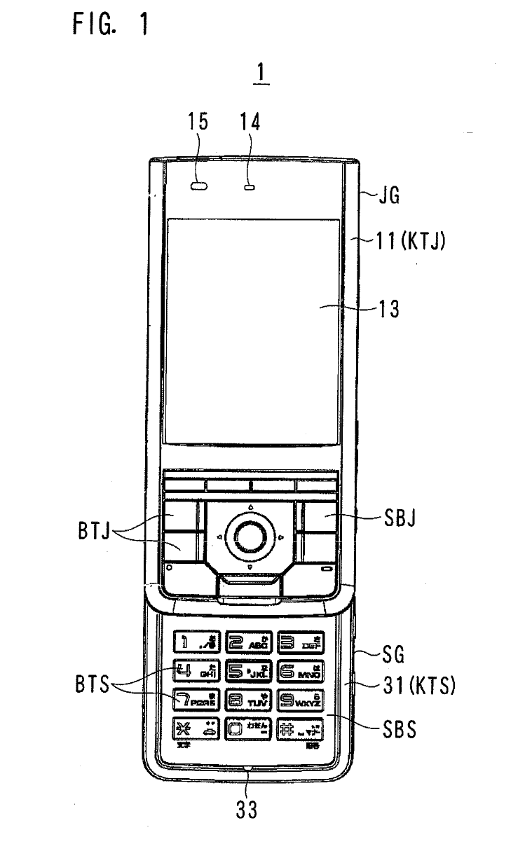

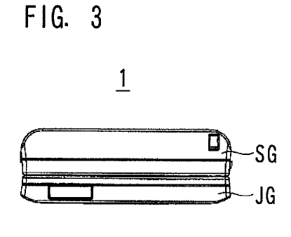

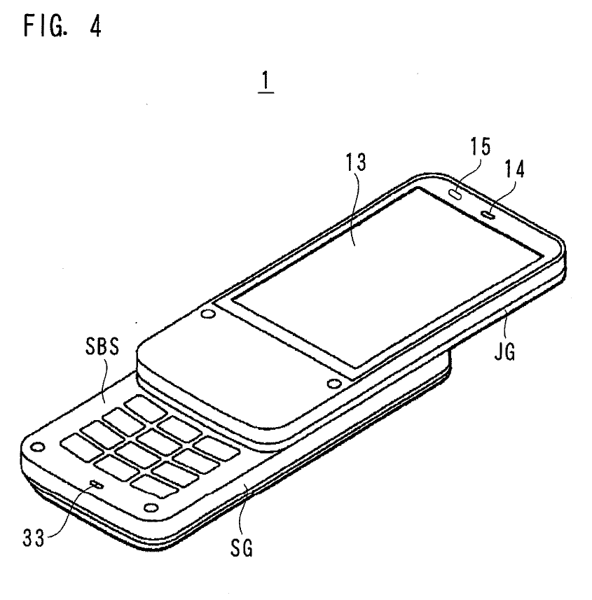

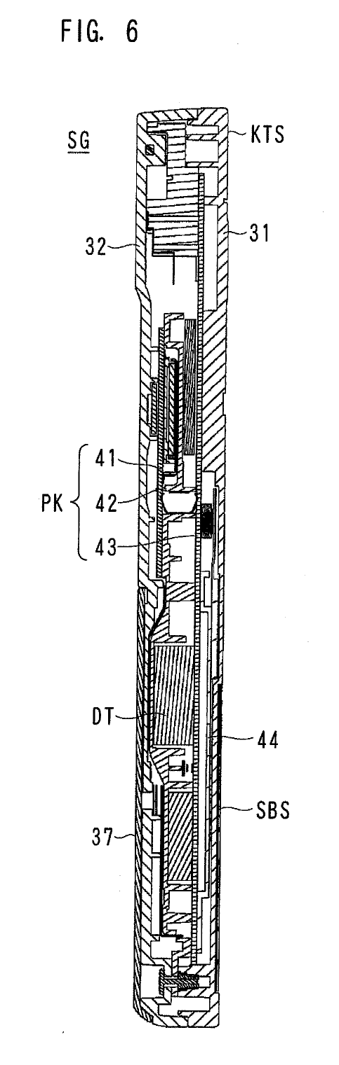

Referring to FIGS. 1-6, a mobile phone 1 according to this embodiment is a sliding mobile phone having a transmitter side (fixed side) SG and a receiver side (movable side) JG coupled by a slide mechanism SK.

A casing KTJ of the receiver side JG includes a front case 11, and a rear case 12 arranged to make contact with the rear of the front case 11. Each of the front case 11 and the rear case 12 is formed by molding a synthetic resin such as a polycarbonate resin or an ABS resin. A front case 31 and a rear case 32, which are described later, are also formed by molding a resin in a manner similar to the case of the front case 11 and the rear case 12.

A surface of the front case 11 is provided with a display 13 implemented by a color LCD, a voice output hole 14 for externally transmitting voice outputted by a built-in speaker for a receiver, and an optical window 15 of a built-in imaging portion (camera). Referring to FIG. 1, the voice output hole 14 and the optical window 15 are provided above the display 13. A lower part of the front case 11 is provided with an operation portion SBJ that has various operation buttons BTJ used to perform various settings and to select a function. The structure of the receiver side JG will be detailed later.

A casing KTS of the transmitter side SG includes the front case 31 having an operation portion SBS on a surface of the front case 31, and the rear case 32 arranged to make contact with the rear of the front case 31. The operation portion SBS has various operation buttons BTS used to enter telephone numbers and other information. The operation portion SBS is so configured that contacts or sensors formed on a printed circuit board, which is described later, detect that the operation button BTS has been pressed. The front case 31 has a voice input hole 33 for transmitting user's voice to a built-in microphone. Referring to FIG. 1, the voice input hole 33 is provided below the operation portion SBS of the front case 31.

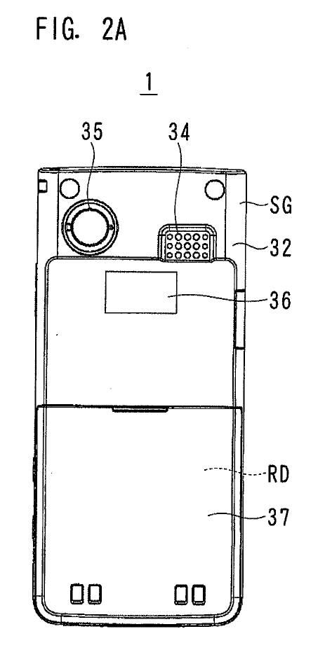

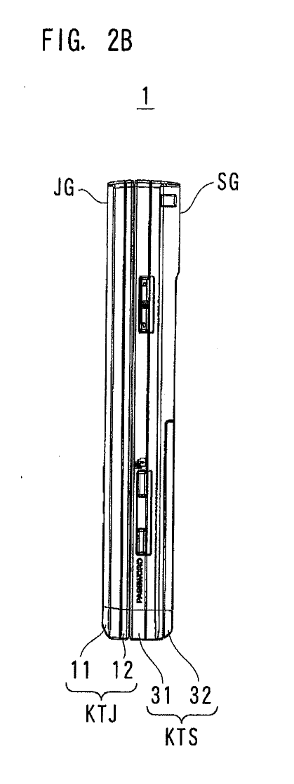

As illustrated in FIG. 2A, the rear case 32 is provided with a voice output hole 34 for externally transmitting voice outputted by a speaker, an optical window 35 of a built-in imaging portion (camera) 208b, a fingerprint sensor window 36 used for fingerprint authentication, and the like. A battery containing portion RD is provided inside the rear case 32, and a detachable battery cover 37 is provided on a surface of the rear case 32.

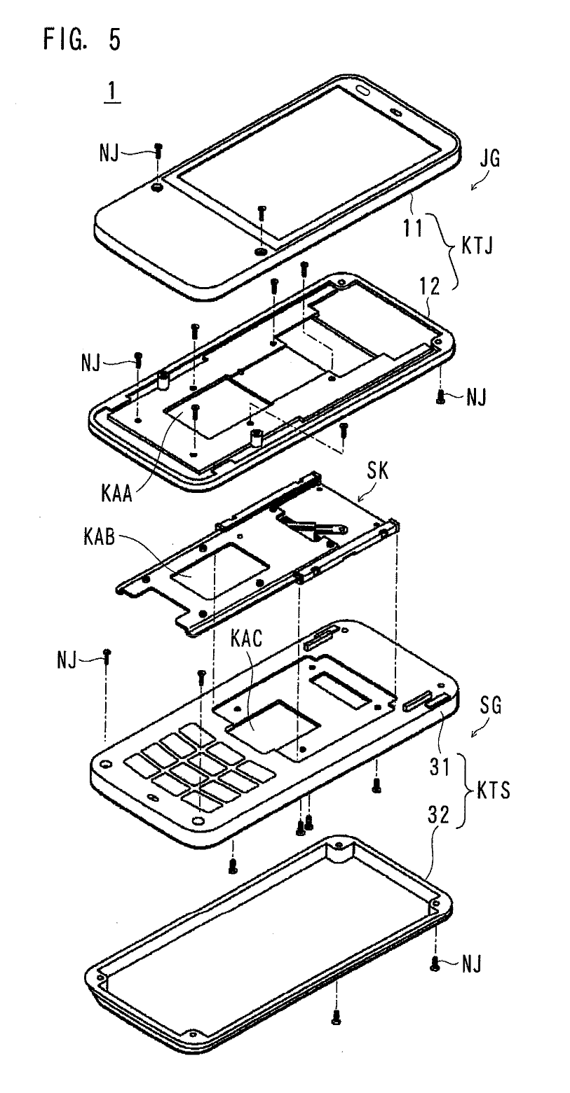

Referring to FIG. 5, the front case 11 and the rear case 12 are coupled to each other by a plurality of screws NJ with necessary components housed therebetween, so that the front case 11 and the rear case 12 are integrated with each other. Likewise, the front case 31 and the rear case 32 are coupled to each other by a plurality of screws NJ with necessary components housed therebetween, so that the front case 31 and the rear case 32 are integrated with each other. The transmitter side SG and the receiver side JG are slidably coupled to each other by the slide mechanism SK provided therebetween.

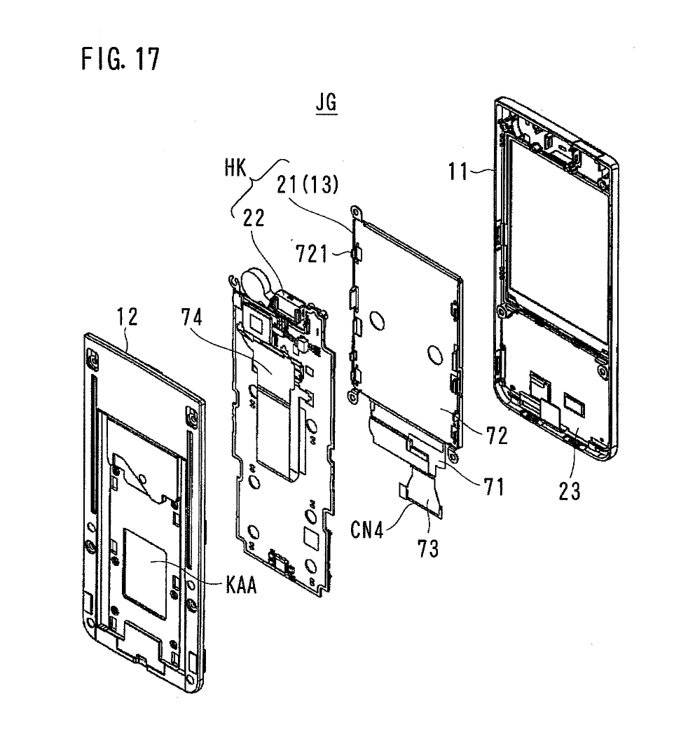

In this embodiment, a main printed circuit board is disposed on the transmitter side SG. A flexible cable (see FIG. 17) connected to the display 13 and the operation buttons BTJ of the receiver side JG is inserted through a hole KAA formed on the rear case 12 of the receiver side JG, a hole KAB formed on the slide mechanism SK, and a hole KAC formed on the front case 11 of the transmitter side SG, and is pulled inside the casing KTS of the transmitter side SG.

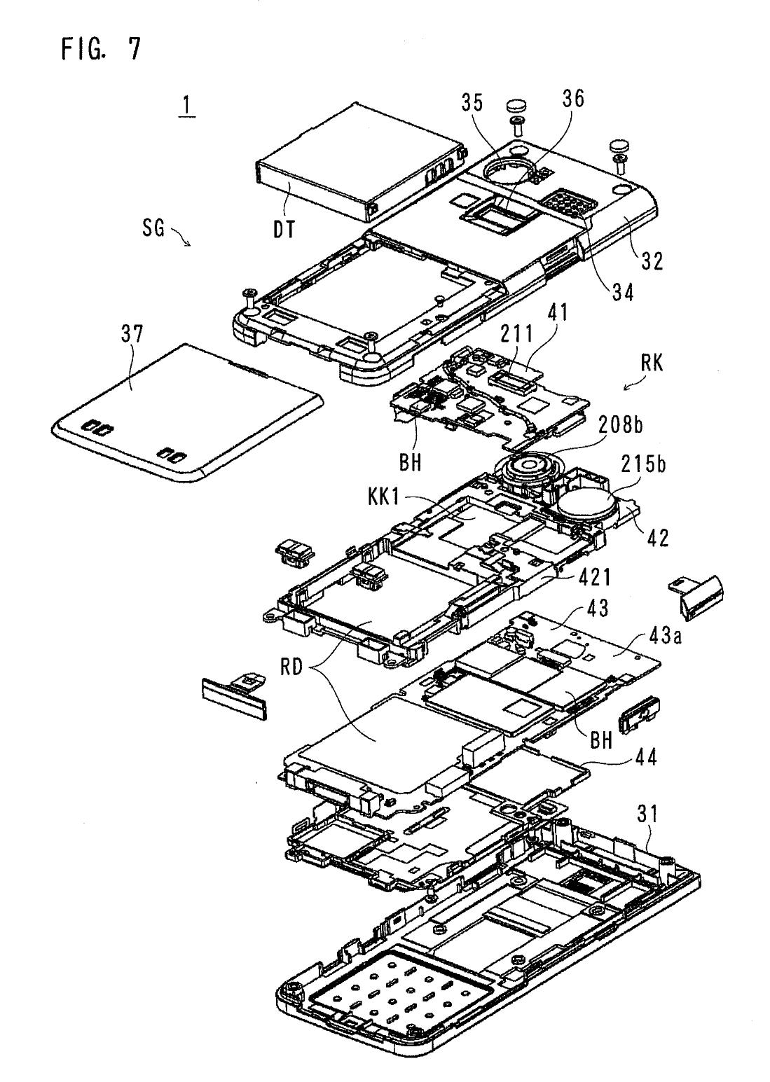

Referring to FIG. 7, the casing KTS of the transmitter side SG has, therein, a sub circuit board 41 that is an auxiliary printed circuit board, an intermediate support member 42, a main circuit board 43 that is a main printed circuit board, an operation circuit board 44, and the like.

Each of the sub circuit board 41 and the main circuit board 43 has an LSI, an IC, a variety of connectors, a flexible cable, and various other electronic components BH mounted thereon. The operation circuit board 44 has, thereon, contacts and sensors for detecting that the operation buttons BTJ have been pressed and inputting the detection.

The intermediate support member 42 is formed by molding a synthetic resin, and serves to support the sub circuit board 41 and the main circuit board 43.

Components such as the imaging portion 208b and a speaker 215b, and a charging electrode are attached to the intermediate support member 42.

A part of the surface of the main circuit board 43 and a part of the frame of the intermediate support member 42 constitute the battery containing portion RD. A battery DT is housed in the battery containing portion RD, and the battery cover 37 is attached to the upper portion thereof.

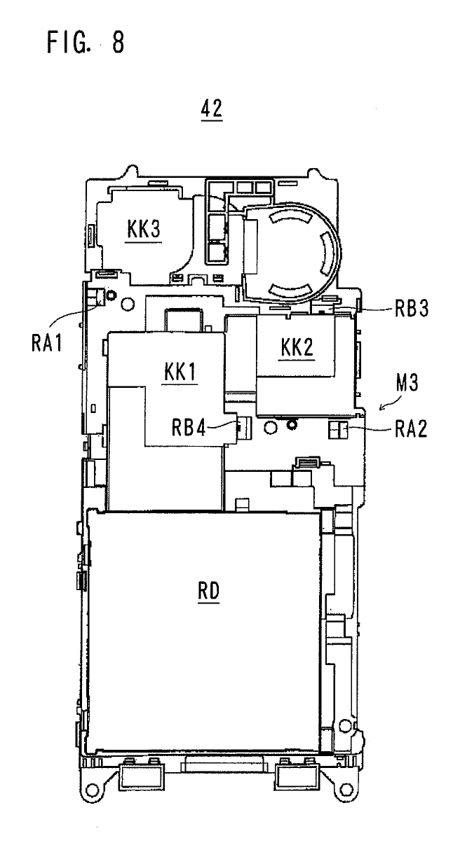

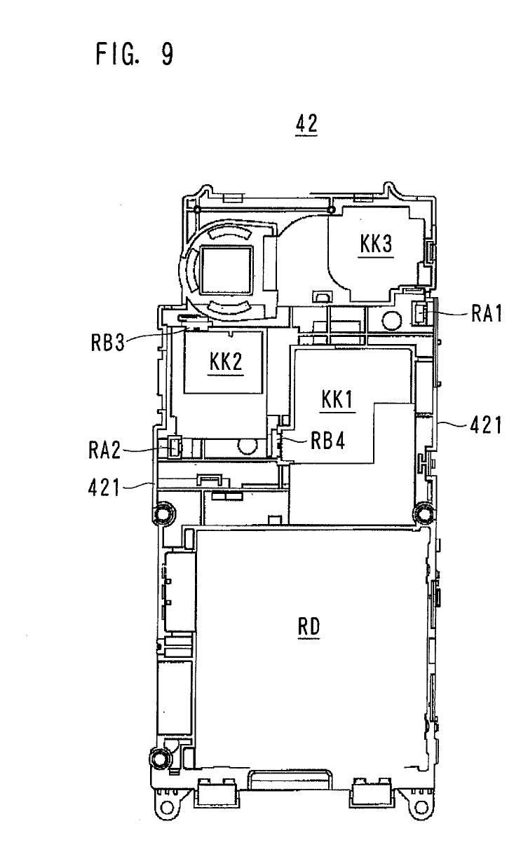

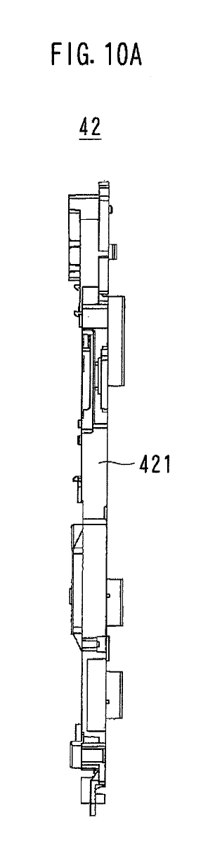

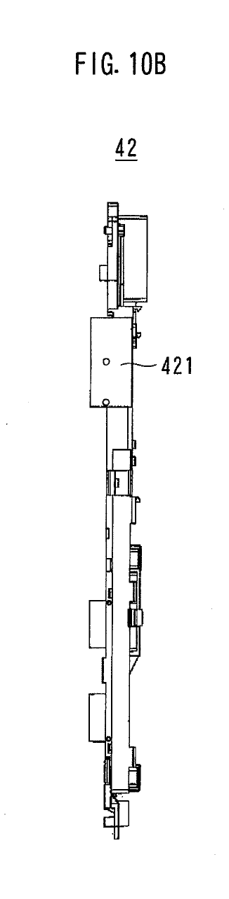

The intermediate support member 42 will be described next with reference to FIGS. 8-10B. FIG. 8 is a diagram illustrating the intermediate support member 42 when viewed from the side of the rear case 32; FIG. 9 is a diagram illustrating the intermediate support member 42 when viewed from the side of the front case 31; FIG. 10A is a right side view of FIG. 8; and 10B is a left side view of FIG. 8.

Referring to FIGS. 8-10B, the intermediate support member 42 has a shape similar to that of the main circuit board 43. The intermediate support member 42 intermittently has a wall 421 extending along the thickness of the intermediate support member 42 along an outer circumferential portion of the shape of the intermediate support member 42. The intermediate support member 42 also has spaces KK1, KK2, and KK3, connection holes RA1 and RA2, and connection recesses RB3 and RB4, in addition to the space corresponding to the battery containing portion RD. The imaging portion 208b is fitted into the space KK3 and is fixed to the intermediate support member 42.

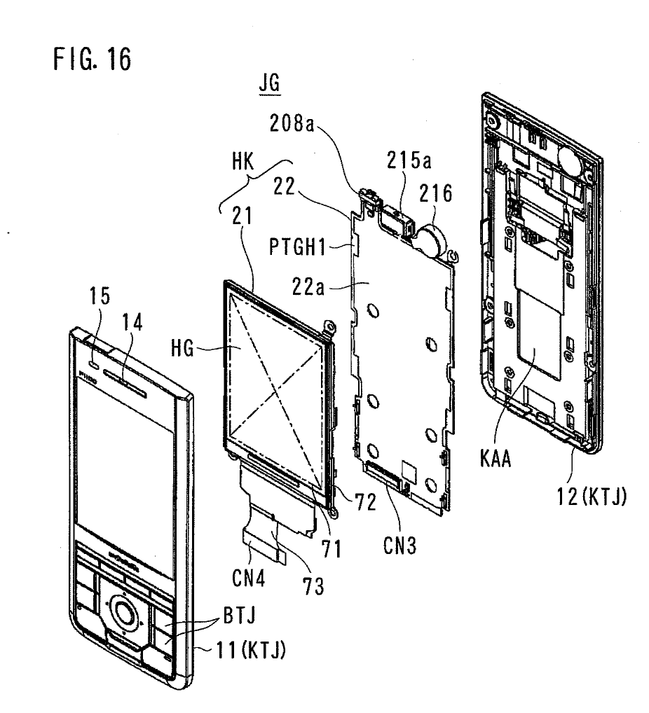

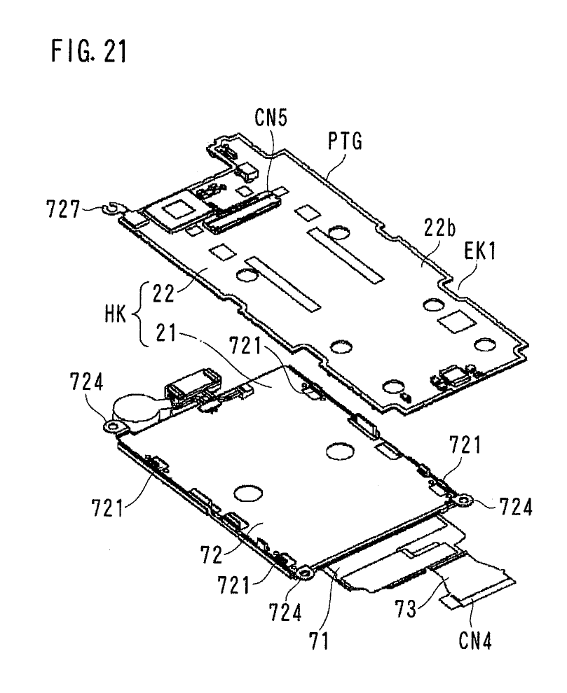

A connection electrode (see FIGS. 16-21) is attached to the connection hole RA. The connection electrode is to connect a ground line GL between the sub circuit board 41 and the main circuit board 43 that are provided to sandwich the intermediate support member 42 therebetween. Specifically, the sub circuit board 41 and the main circuit board 43 have common electrodes, which are ground patterns PTGM or PTGS described later, in such a manner that the common electrodes face each other. The intermediate support member 42 is provided with the connection holes RA, which are through holes, at positions corresponding to the positions where the common electrodes are provided. The connection electrode that has, on both ends of the connection electrode, electrical contacts, is provided with a catch portion, and is made of an electrical conductive material is inserted into the connection hole RA. Further, the catch portion engages with the connection hole RA and the connection electrode is retained in the connection hole RA. The two electrical contacts of the connection electrode come to contact with the common electrodes provided on the sub circuit board 41 and the main circuit board 43, so that the sub circuit board 41 and the main circuit board 43 are electrically connected to each other. This provides a solid ground connection. The details will be provided later.

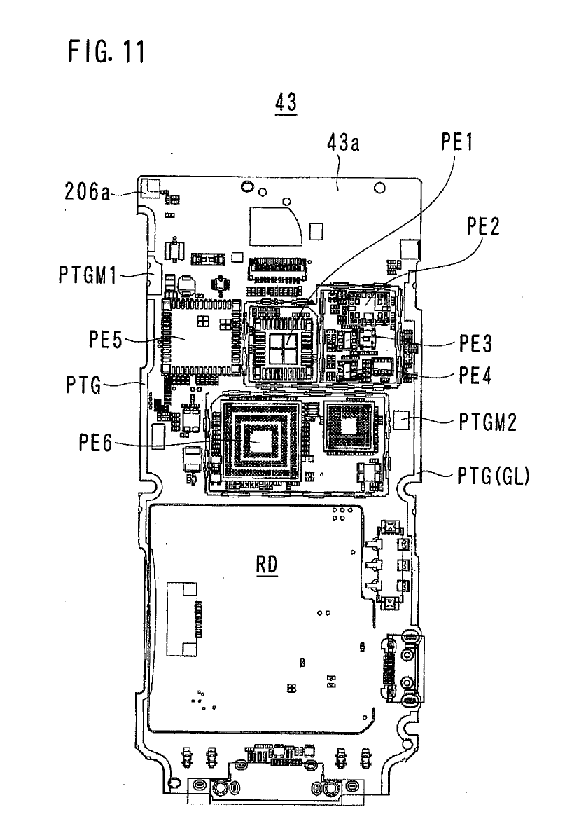

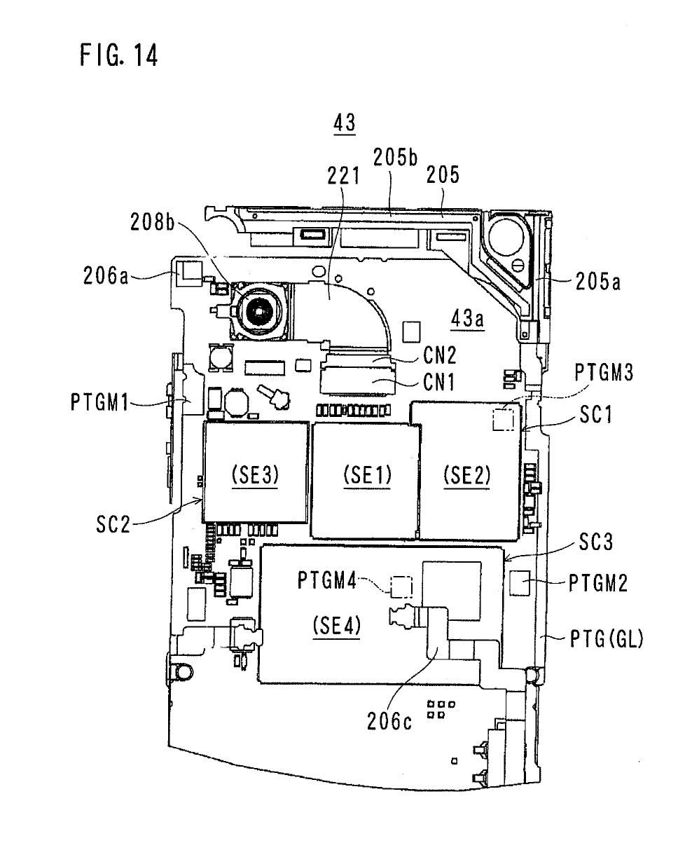

The following is a description of the main circuit board 43 and the sub circuit board 41 with reference to FIGS. 11-14. FIGS. 11-13B illustrate individual printed circuit board patterns without electronic components such as LSIs. FIG. 14 illustrates a state in which electronic components are mounted on the main circuit board 43.

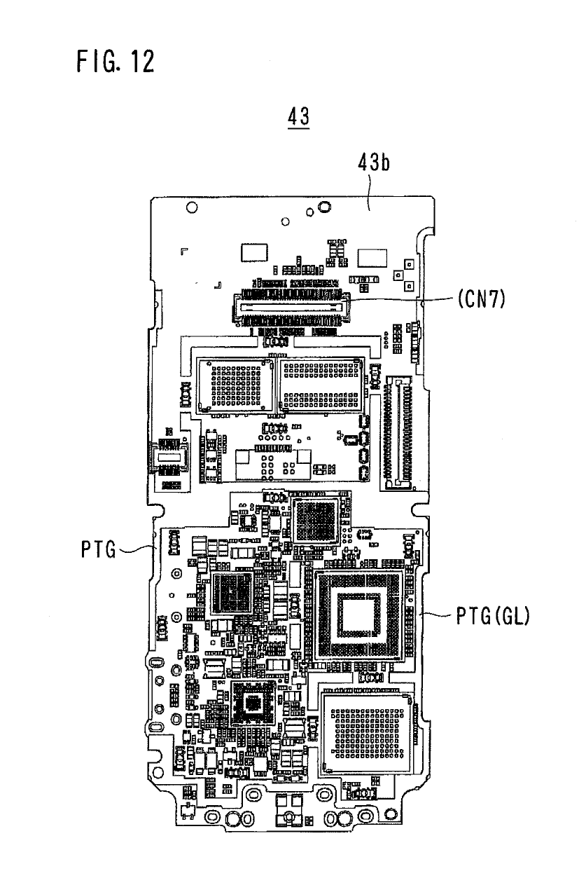

Referring to FIGS. 11 and 12, a variety of LSIs and electronic components are soldered onto a front surface 43a and a back surface 43b of the main circuit board 43 by using a surface-mount technology.

For example, a TRX module for WCDMA having a frequency modulation function or a frequency multiplication function is mounted in a pattern area PE1 of the front surface 43a illustrated in FIG. 11. An RF-LSI for WCDMA having a duplexer function is mounted in a pattern area PE2 of the front surface 43a. An LSI for a 2 GHz power amplifier is mounted in a pattern area PE3. An LSI for an 800 MHz power amplifier is mounted in a pattern area PE4. An LSI module for a wireless LAN is mounted in a pattern area PE5. An LSI for dominating the control or processing of the CPU or the DSP is mounted in a pattern area PE6.

The electronic components described above are mounted in the individual pattern areas PE1-PE6, and are covered with shield cases SC for electromagnetic shielding as illustrated in FIG. 14. To be specific, the shield case SC1 is attached to shield the electronic components and circuits mounted in the pattern areas PE1-PE4. The shield cases SC2 and SC3 are attached to shield the electronic components and circuits mounted in the pattern areas PE5 and PE 6, respectively.

Referring to FIG. 11, a 5 GHz antenna element 206a is provided in an upper left end of the main circuit board 43. The antenna element 206a is formed by print patterning and used for a wireless LAN corresponding to short distance radio communication.

Each of the front surface 43a and the back surface 43b of the main circuit board 43 has, on an outer circumferential portion of the main circuit board 43, ground patterns PTG constituting a ground line GL. Since the main circuit board 43 is a multi layer circuit board, the ground patterns PTG are connected to one another in an inner layer of the main circuit board 43 even if they do not appear to be connected on the surface thereof. Thus, the ground patterns PTG are intermittently observed on the surface of the main circuit board 43. The ground patterns PTGM1 and PTGM2 illustrated in FIG. 11 are also a part of the ground patterns PTG.

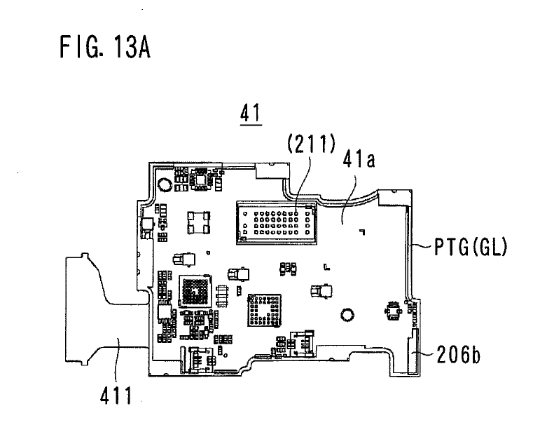

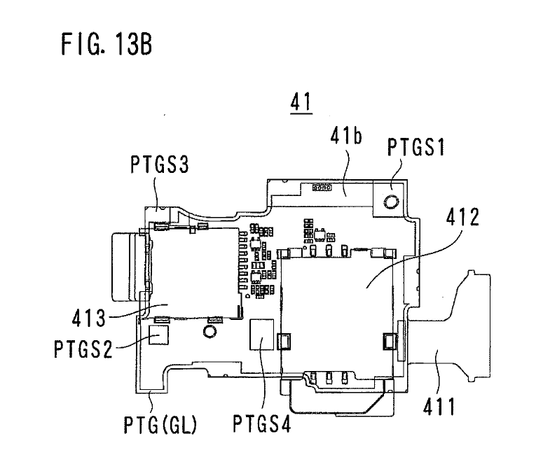

Referring to FIGS. 13A and 13B, a variety of LSIs and electronic components are soldered onto a front surface 41a and a back surface 41b of the sub circuit board 41 by using a surface-mount technology. For example, a fingerprint sensor 211 is mounted on the front surface 41a. A SIM card 412, a micro SD memory 413, and the like are mounted on the back surface 41b. Further, a flexible cable 411 is connected to the sub circuit board 41. A connector provided in an end of the flexible cable 411 is connected to a connector provided in the main circuit board 43, thereby to establish a connection between the circuits of the sub circuit board 41 and the circuits of the main circuit board 43.

As with the main circuit board 43, each of the front surface 41a and the back surface 41b of the sub circuit board 41 has, on an outer circumferential portion of the sub circuit board 41, ground patterns PTG. The ground patterns PTGS1-PTGS4 illustrated in FIG. 13B are also a part of the ground patterns PTG.

The ground patterns PTGM1 and PTGM2 of the main circuit board 43 are so provided that the ground patterns PTGM1 and PTGM2 respectively face the ground patterns PTGS1 and PTGS2 of the sub circuit board 41. Further, the ground pattern PTGM1 and the ground pattern PTGS1 correspond to the connection hole RA1, and the ground pattern PTGM2 and the ground pattern PTGS2 correspond to the connection hole RA2. The connection electrodes inserted into the connection holes RA1 and RA2 enable the ground patterns PTGM and PTGS facing each other to be electrically connected to each other. This provides a solid ground connection between the main circuit board 43 and the sub circuit board 41. Note that the ground patterns PTG, i.e., the ground line GL is connected to the negative side of the battery DT.

Referring to FIG. 14, a connector CN1 provided on the front surface 43a of the main circuit board 43 is connected to a connector CN2 of an end of a flexible cable (flexible circuit board) 221 connected to the imaging portion 208b. Further, an antenna element 205 for long distance radio communication is provided along the upper side of the inside surface of the rear case 32, i.e., in the vicinity of the upper end of the main circuit board 43. The antenna element 205 is a dual band antenna including an antenna element 205a for transmission and reception of radio waves in 2 GHz frequency band, and an antenna element 205b for transmission and reception of radio waves in 800 Mhz frequency band.

In FIG. 14, an antenna element 206b (see FIG. 13A) for transmission and reception of radio waves in 2.4 GHz frequency band is provided. The antenna element 206b is formed by print patterning and used for a wireless LAN corresponding to short distance radio communication. The antenna element 206b is connected to the wireless LAN circuit of the main circuit board 43 via a coaxial cable (not illustrated). In FIG. 14, a loop antenna element 206c using a flexible cable for Felica (registered trademark) is provided. Felica is a non-contact communication standard corresponding to a type of the short distance radio communication.

The entire circuit of the mobile phone 1 will be described next.

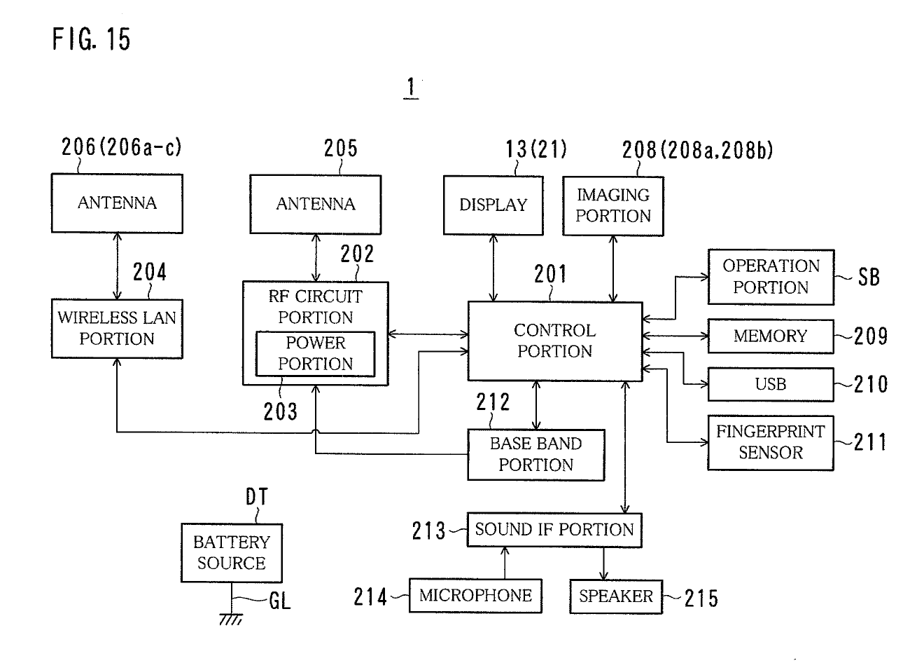

Referring to FIG. 15, the mobile phone 1 includes a control portion 201, an RF circuit portion 202, a power portion 203, a wireless LAN portion 204, the antenna elements 205 (205a and 205b) and 206 (206a-206c), the display 13, the imaging portions 208 (208a and 208b), the operation portion SB, a memory 209, a USB interface portion 210, the fingerprint sensor 211, a base band portion 212, a sound IF portion 213, a microphone 214, and the speakers 215 (215a and 215b).

The control portion 201 is implemented by the CPU or the DSP, and is operable to control the operation of the individual portions of the mobile phone 1 and the entire operation thereof. The control portion 201 executes a variety of operating systems and application programs stored in the memory, so that it performs a variety of processes or implements a variety of functions.

The RF circuit portion 202 corresponds to a “long distance radio communication portion” according to the present invention. The RF circuit portion 202 enables the mobile phone 1 to communicate with a fixed station (base station) in a wireless network. The RF circuit portion 202 has a hand-over function by means of which the mobile phone 1 is capable of performing communication by switching between a plurality of fixed stations. The power portion 203 is disposed mainly in the pattern areas PE1-PE3.

The wireless LAN portion 204 corresponds to a “short distance radio communication portion” according to the present invention. The wireless LAN portion 204 performs radio communication having a communication distance shorter than that in the RF circuit portion 202.

Each of the RF circuit portion 202 and the wireless LAN portion 204 has a communication portion compatible with a plurality of communication standards. Each of the RF circuit portion 202 and the wireless LAN portion 204 is compatible with communication standards such as FORMA-B, WCDMA, WiMAX, and wireless LAN, and has a function to hand over to fixed stations for the different communication standards. The RF circuit portion 202 and the wireless LAN portion 204 are configured to be compatible with, as the wireless LAN, a variety of communication standards such as Bluetooth, WirelessUSB, and RF-ID.

Examples of the memory 209 are the SIM card 412, the micro SD memory 413, a semiconductor memory, and a magnetic disk. The SIM card 412 stores, thereon, information on communication and personal information on a user such as a telephone number, a SIP address, and an IP address. The micro SD memory 413 stores, therein, for example, image data obtained by shooting, sent and received electronic mail messages, data downloaded from a network, and data on address book.

The USB interface portion 210 enables the mobile phone 1 to connect to a USB interface of a personal computer, or to connect to an electronic device having a USB interface.

A power necessary for such operation is supplied from the battery DT, a personal computer via the USB interface portion 210, or a charger (not illustrated) via a connector.

The following is a description of the structure of the receiver side JG, in particular, a contact structure for ground connection between a display panel 21 and a display circuit board 22 in the display panel structure HK. Note that the display panel structure HK and components therearound constitute the display 13.

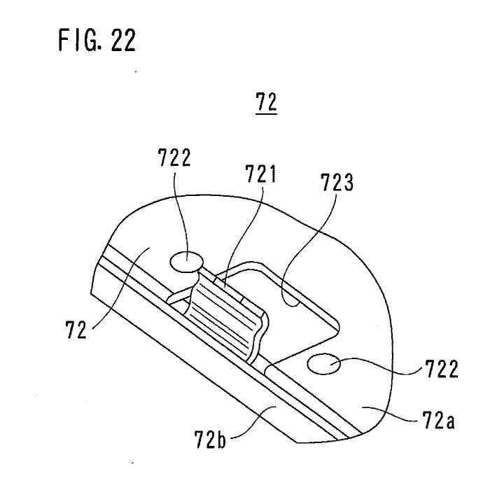

Referring to FIGS. 16-22, the casing KTJ of the receiver side JG has, therein, the display panel 21, the display circuit board 22 that is a printed circuit board for display, an operation circuit board 23, and the like.

The display panel 21 includes a display element 71 having, on a front face of the display element 71, a screen HG, and a metal holding member 72 for holding the display element 71 together on the back side of the display element 71. The holding member 72 is provided with a plurality of catch portions 721 that extend from the back side of the holding member 72 and grip end edge portions of the display circuit board 22. The holding member 72 is also provided with a plurality of projections 722 that project, around the catch portions 721, from the back side of the holding member 72. The display circuit board 22 is gripped by the catch portions 721 provided on the back side of the holding member 72, and the ground patterns PTGH1-PTGH4 provided on the surface of the display circuit board 22 come into close contact with the projections 722, thereby an electrical connection is made between the display panel 21 and the display circuit board 22.

As described above, the display panel 21 and the display circuit board 22 constitute the display panel structure HK. The display circuit board 22 is gripped by the catch portions 721, and the projections 722 come into close contact with the ground patterns PTGH1-PTGH4 of the display circuit board 22. Thereby, the conduction is positively achieved between the display panel 21 and the display circuit board 22, so that the ground connection therebetween is ensured.

Further, the catch portions 721 and the projections 722 are provided in the holding member 72, for example, by sheet metal processing. It is therefore unnecessary to increase the number of components, so that the structure becomes less complex. Since the display panel structure HK is an integrated structure, it is unnecessary to fasten the entire display panel structure HK to the casing KTJ with the screws NJ or the like, which makes it possible to reduce the thickness of the casing KTJ.

The catch portions 721 are formed at, in total, four positions. To be specific, two catch portions 721 are formed at individual positions close to the both ends of the long sides of the holding member 72. Two projections 722 are provided around each of the catch portions 721.

The catch portions 721 may be formed at five or more positions. One projection 722 may be provided around each of the catch portions 721. In the case where one projection 722 is provided around each of the catch portions 721, the projection 722 may be formed ahead of the center of the catch portion 721, or may be formed ahead of a side thereof. In the case where one projection 722 is formed ahead of a side of one of the catch portions 721 adjacent to each other, the projection 722 is preferably formed on a side close to the other of the catch portions 721.

The display panel 21 is connected to one end of the flexible cable 73, and the other end of the flexible cable 73 is provided with a connector CN4. The connector CN4 is connected to a connector CN3 provided on a front surface 22a of the display circuit board 22.

The flexible cable 73 includes a signal line SL necessary for control of the display element 71 and transfer of image data, and the ground line GL.

The display element 71 is a color liquid crystal display element as described above. The holding member 72 is to increase the mechanical strength of the display element 71 and to prevent the glass from breaking. The insufficient ground connection of the holding member 72 sometimes affects high frequency characteristics in radio communication. According to this embodiment, however, solid ground connections are provided by the catch portions 721 and the projections 722 as discussed above; therefore the antenna characteristics or the like are not harmed.

FIGS. 16 and 17 illustrate the casing KTJ of the receiver side JG, in particular, the receiver speaker 215a, a vibrator 216 for producing a small shaking movement to inform a user of incoming calls/messages, and the flexible cable 74 for connecting the signal line SL and the ground line GL from the display circuit board 22 to the main circuit board 43 of the transmitter side SG. The flexible cable 74 has one end connected to a connector CN5 provided on a back surface 22b of the display circuit board 22, and the other end connected to a connector CN7 provided on the back surface 43b of the main circuit board 43.

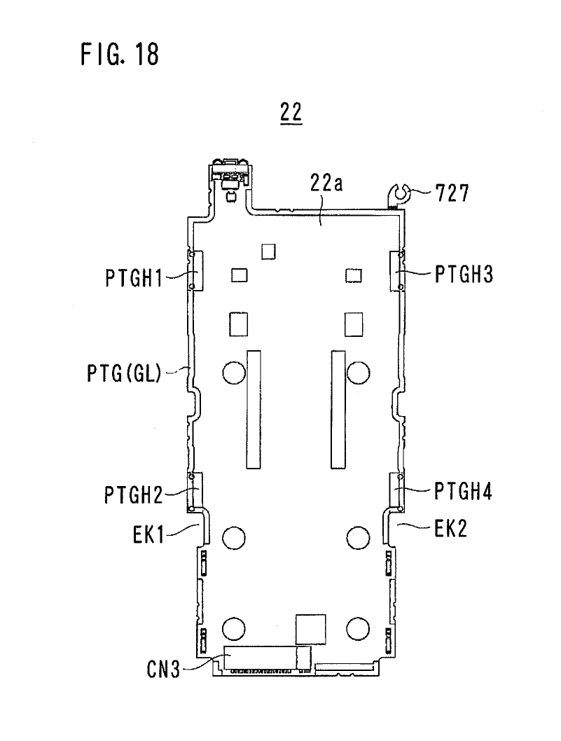

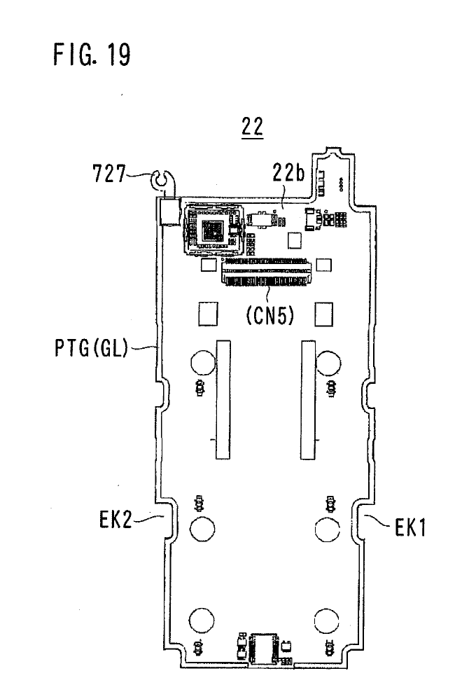

Referring to FIGS. 18 and 19, each of the front surface 22a and the back surface 22b of the display circuit board 22 is provided with ground patterns PTG, i.e., a ground line GL along the circumferential portion thereof. The ground patterns PTGH1-PTGH4 are formed on the front surface 22a at individual positions corresponding to the positions where the catch portions 721 are provided. The width of the ground patterns PTGH1 -PTGH4 is increased at the individual positions. With the display circuit board 22, the connector CN3 and the connector CN5 are connected to each other via the signal line SL formed as an inner layer.

The shapes of the catch portion 721 and the projection 722 will be described next.

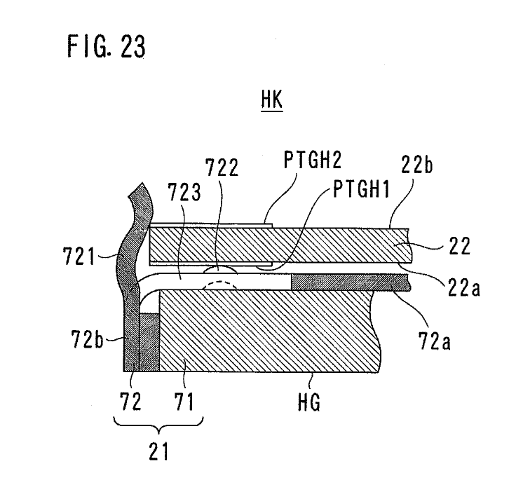

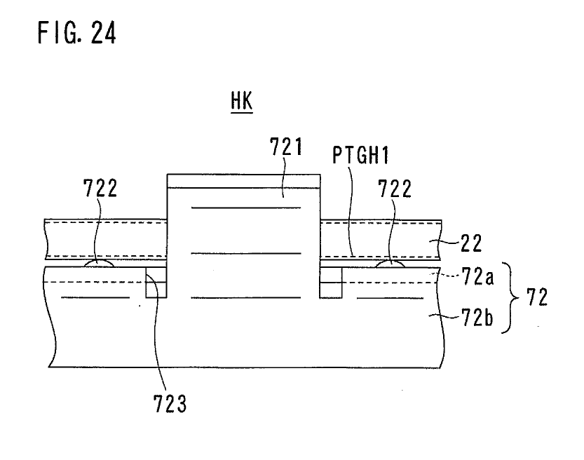

Referring to FIGS. 23-24, the holding member 72 is fabricated by performing sheet metal processing on a stainless steel plate having a thickness of, for example, a few tenths of millimeters. The holding member 72 includes a bottom portion 72a having substantially the same shape as that of the display element 71 as viewed from the front, i.e., having a rectangular shape, and a side wall portion 72b provided by bending the stainless steel plate to form approximate right angles at the four sides of the bottom portion 72a. At the position where the catch portion 721 is to be provided, a notch portion 723 is formed by cutting the bottom portion 72a surrounding the catch portion 721. The residual part after forming the notch portion 723 is bent to have a cross sectional surface with a gentle S-shaped curve on an extension of the side wall portion 72b or close to the extension, so that the catch portion 721 is formed.

The bottom portion 72a is pressed from the inside on both sides of the notch portion 723. Thereby, the pressed portions of the bottom portion 72a bulge out, so that the projections 722 are formed. The projection 722 has a diameter of, for example, approximately a few tenths of millimeters, specifically for example, five tenths of millimeters, and a height of approximately a few hundredths of millimeters, specifically for example, five hundredths of millimeters.

The display circuit board 22 abuts against the display panel 21 in such a manner that edge portions of the display circuit board 22 are fitted into the catch portions 721, and in that state, the display circuit board 22 is strongly pushed into the display panel 21; thereby the edge portions are gripped by the catch portions 721. At this time, the individual catch portions 721 slightly deform outwardly and elastically, and grip the edge portions in such a manner that the display circuit board 22 is pushed against the projections 722 by the elastic force. In this way, the display circuit board 22 is positioned and securely gripped by the action of the catch portions 721. The action of the catch portions 721 ensures the connection between the projections 722 and the ground patterns PTGH1-PTGH4. Thus, the display panel structure HK is provided to have an integrated structure.

As discussed above, each of the catch portions 721 preferably has a shape that facilitates the attachment of the display circuit board 22, and after the attachment, enables the display circuit board 22 to be sandwiched using the elastic force of the catch portion 721, and enables the display circuit board 22 to be pressed against the projection 722, i.e., the bottom portion 72a.

The display panel 21 and the display circuit board 22 are detachable from each other without damaging each other. In the case where the side wall portion 72b is not provided, an extended portion of the bottom portion 72a may be bent and the resultant may be regarded as the catch portion 721.

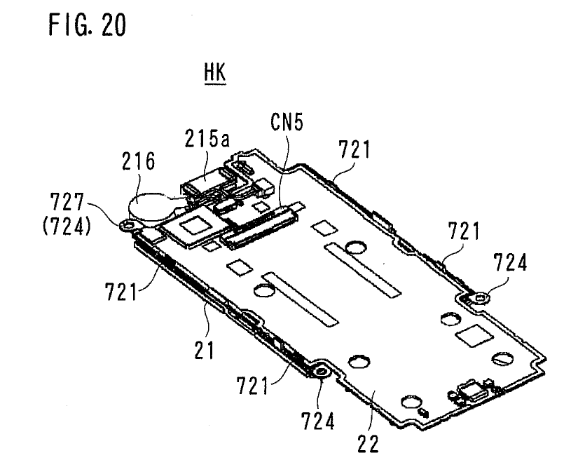

As clearly illustrated in FIG. 20, the holding member 72 has, on three corners of the holding member 72, fixing terminals 724. The display circuit board 22 is provided with two recess portions EK1 and EK2 and one fixing terminal 727 corresponding to the fixing terminals 724 of the holding member 72. The fixing terminal 727 is connected to the ground pattern PTG of the display circuit board 22.

The two recess portions EK1 and EK2 are provided in order to avoid the interference between the display circuit board 22 and the front case 11 for the case where two of the fixing terminals 724 are attached to the front case 11. The fixing terminal 727, one of the fixing terminals 724, and the front case 11 are fastened together with the screws NJ.

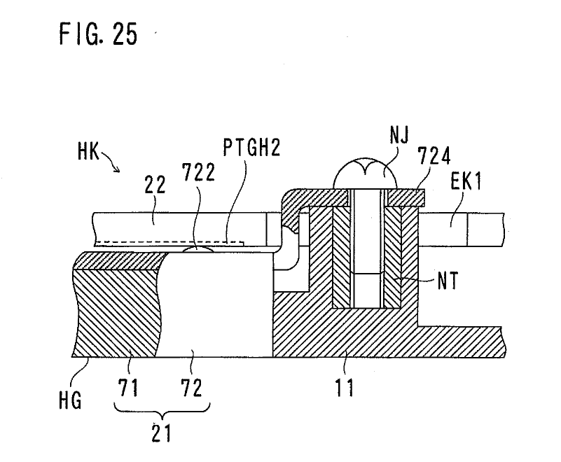

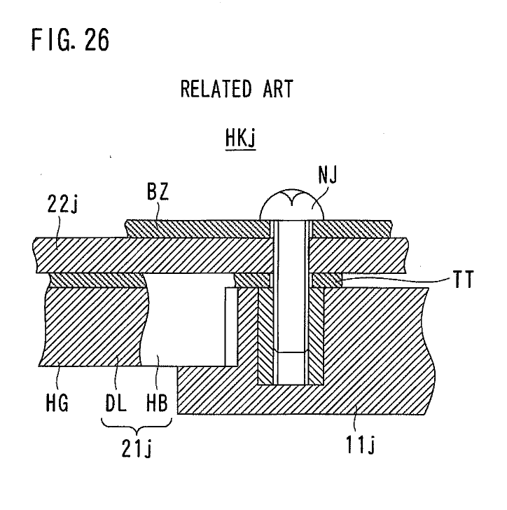

As illustrated in FIG. 25, the display panel structure HK is fitted into a predetermined position of the front case 11, and in this state, the screw NJ inserted into the hole of the fixing terminal 724 is screwed into a nut NT integrated with the front case 11, so that the display panel structure HK is attached to the front case 11.

As discussed above, the display panel structure HK is capable of being fixed to the front case 11 with the screw NJ via the fixing terminal 724 having a small thickness, i.e., a thickness corresponding to the thickness of the holding member 72. Thus, it is possible to reduce the thickness of the casing KTJ.

Another structure is possible in which the screw NJ is inserted from the outside of the rear case 12 or the outside of the slide mechanism SK; thereby the display panel structure HK is fixed to the rear case 12 or the slide mechanism SK with the screw NJ. Yet another structure is possible in which the screw NJ is inserted from the front face of the front case 11 to fix the fixing terminal 724, instead of inserting the screw NJ from the side of the fixing terminal 724.

In the embodiment mentioned above, the description was given of the mobile phone 1 using the display panel structure HK as the display 13. Likewise, the display panel structure HK is applicable to portable information equipment, a mobile terminal, a communication device, an electronic device, or the like apart from the mobile phone 1.

The configuration, structure, shape, dimensions, material, number, control content, and the like of the catch portion 721, the projection 722, the display element 71, the holding member 72, the display panel 21, the display circuit board 22, the display panel structure HK, the mobile phone 1, or the entirety or individual portions of the mobile phone 1 may be suitably modified without departing from the gist of the invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A display panel structure comprising:
a display panel; and
a printed circuit board, wherein
the display panel includes a display element having, on a front face of the display element, a screen, and a metal holding member for holding the display element together on a back face of the display element,
the holding member is provided with a plurality of catch portions that extend from a back face of the holding member and grip end edge portions of the printed circuit board, and is also provided with a plurality of projections that project, around each of the plurality of catch portions, from the back face of the holding member, and
the printed circuit board is gripped by the plurality of catch portions provided on the back face of the holding member, and ground patterns provided on a surface of the printed circuit board come into close contact with the plurality of projections, so that an electrical connection is made between the display panel and the printed circuit board.

2. The display panel structure according to claim 1,
wherein an amount of the plurality of catch portions is four or more, and
electrical connections are made between the display panel and the printed circuit board at four positions or more by close contact between the plurality of projections and the ground patterns.

3. The display panel structure according to claim 2, wherein two of the plurality of projections are provided around said each of the plurality of catch portions.

4. The display panel structure according to claim 1,
wherein the display panel is connected to one end of a flexible cable, and another end of the flexible cable is provided with a connector, and
the connector of the flexible cable is connected to a connector provided in the printed circuit board.

5. The display panel structure according to claim 1,
wherein the display element is a color liquid crystal display element, and
the holding member increases mechanical strength of the display element.

6. An electronic device comprising:
a casing; and
a display panel structure fixed inside the casing, wherein
the display panel structure comprises a display panel and a printed circuit board,
the display panel includes a display element having, on a front face of the display element, a screen, and a metal holding member for holding the display element together on a back face of the display element,
the holding member is provided with a plurality of catch portions that extend from a back face of the holding member and grip end edge portions of the printed circuit board, and is also provided with a plurality of projections that project, around each of the plurality of catch portions, from the back face of the holding member, and
the printed circuit board is gripped by the plurality of catch portions provided on the back face of the holding member, and ground patterns provided on a surface of the printed circuit board come into close contact with the plurality of projections, so that an electrical connection is made between the display panel and the printed circuit board.

7. The electronic device according to claim 6, further comprising
a long distance radio communication portion that is configured to communicate with one of a plurality of fixed stations, and has a hand-over function by means of which the electronic device is capable of performing communication by switching between the plurality of fixed stations, and
a short distance radio communication portion that performs radio communication having a communication distance shorter than that in the long distance radio communication portion,
wherein the long distance radio communication portion has a communication portion compatible with a plurality of communication standards, and
the short distance radio communication portion has a communication portion compatible with a plurality of communication standards.

8. The electronic device according to claim 7, further comprising an antenna element provided in a vicinity of the display panel structure, the antenna element being used for radio communication by the long distance radio communication portion.

9. Mobile information equipment comprising
a casing;
a display panel structure fixed inside the casing;
a long distance radio communication portion that is configured to communicate with one of a plurality of fixed stations, has a hand-over function by means of which the electronic device is capable of performing communication by switching between the plurality of fixed stations, and has a communication portion compatible with a plurality of communication standards;
a short distance radio communication portion that performs radio communication having a communication distance shorter than that in the long distance radio communication portion, and has a communication portion compatible with a plurality of communication standards;
an antenna element that is provided in a vicinity of the display panel structure and is used for radio communication by the long distance radio communication portion; and
an operation portion that performs operation on the long distance radio communication portion and the short distance radio communication portion,
wherein the display panel structure comprises a display panel and a printed circuit board,
the display panel includes a display element having, on a front face of the display element, a screen, and a metal holding member for holding the display element together on a back face of the display element,
the holding member is provided with a plurality of catch portions that extend from a back face of the holding member and grip end edge portions of the printed circuit board, and is also provided with a plurality of projections that project, around each of the plurality of catch portions, from the back face of the holding member, and
the printed circuit board is gripped by the plurality of catch portions provided on the back face of the holding member, and ground patterns provided on a surface of the printed circuit board come into close contact with the plurality of projections, so that an electrical connection is made between the display panel and the printed circuit board.
